(19) United States
(12) Patent Application Publication
(10) Pub. No.: US 2015/0200166 A1
(43) Pub. Date: Jul. 16, 2015

(54) SEMICONDUCTOR DEVICE, AND MANUFACTURING METHOD OF SEMICONDUCTOR DEVICE

(71) Applicant: TERA PROBE, INC., Yokohama City (JP)

(72) Inventors: Ichiro KONO, Higashiyamato-shi (JP); Kazufumi NOMURA, Akishima-shi (JP); Masato FUKUSHIMA, Tokorozawa-shi (JP)

(73) Assignee: TERA PROBE, INC., Yokohama City (JP)

(21) Appl. No.: 14/597,823

(22) Filed: Jan. 15, 2015

(30) Foreign Application Priority Data
Jan. 16, 2014 (JP) 2014-006111

(51) Int. Cl. H01L 23/00; H01L 27/108; H01L 23/28; H01L 21/56; H01L 23/525

(52) U.S. Cl. CPC H01L 23/564; H01L 21/56; H01L 24/03; H01L 23/5256; H01L 23/28; H01L 27/108; H01L 27/10844; H01L 2924/01022; H01L 2924/01073; H01L 2924/0132; H01L 2924/37001; H01L 2224/0231

(57) ABSTRACT

A manufacturing method of a semiconductor device includes thermally curing a thermosetting resin material layer formed on a semiconductor wafer at a first temperature of 100° C. to 200° C. to form a protective film, preheating the semiconductor wafer having the protective film formed therein at a second temperature and removing water on the surface of the protective film, bias sputtering on the preheated semiconductor wafer, then controlling the temperature of the semiconductor wafer to a third temperature of not more than 200° C., and sputtering a material selected from the group consisting of Ti, TiW, Ta, and a conductive Ti compound to form a first conductive underlayer on the protective film.

### CROSS-REFERENCE TO RELATED APPLICATIONS

This application is based upon and claims the benefit of priority from prior Japanese Patent Application No. 2014-006111, filed Jan. 16, 2014, the entire contents of which are incorporated herein by reference.

### BACKGROUND OF THE INVENTION

1. Field of the Invention

The present invention relates to a semiconductor device, and a manufacturing method of a semiconductor device.

2. Description of the Related Art

Manufacturing processes of a semiconductor device are mostly classified into a wafer fabrication process (front end process), a wafer test process, an assembly process, and a final test process. The wafer fabrication process is a process for forming an integrated circuit on the surface of a semiconductor wafer which is mostly made of a silicon material by subjecting the semiconductor wafer to a film formation treatment, a photolithographic treatment, an etching treatment, and a doping treatment.

Characteristic degradation occurring in the integrated circuit in the wafer fabrication process are difficult to find in the wafer fabrication process. Therefore, in the subsequent wafer test process, the circuit is inspected for characteristic degradation such as breaking of a wire and a short circuit. In the event of an electric trouble, the integrated circuit may be electrically adjusted to restore the integrated circuit from the electric trouble, for example, by cutting a fuse wire of the integrated circuit with laser and replacing the circuit with a redundant circuit.

In the final process of the wafer fabrication, an insulating layer is stacked, and the integrated circuit is protected by the insulating layer. A fuse opening is formed in the insulating layer and the fuse wire is exposed through the fuse opening so that laser can be applied to the fuse wire in the subsequent wafer test process.

The assembly process is a process for dividing the semiconductor wafer into chips, and packaging nondefective chips on the basis of information obtained as a result of the wafer test process.

The final test process is a process for conducting, for example, a final inspection of a semiconductor product after the assembly process.

A wafer level package (WLP) is known as a package of the semiconductor device. In an assembly process of the WLP, a protective film, a redistribution layer, and an external connection electrode are formed on a semiconductor wafer before divided into chips, and the semiconductor wafer is then divided into chips, in contrast with the previously described method.

In a manufacturing method of a semiconductor device using the WLP, an internal circuit is first formed on the surface of a semiconductor wafer. A connection pad which is electrically connected to the internal circuit is further provided. After the connection pad and the internal circuit are covered with a passivation film, the passivation film on the connection pad is removed by etching, and a protective film made of, for example, polyimide, is formed on the passivation film. This protective film can be formed by coating the passivation film with an insulating resin material such as polyimide having positive or negative photosensitivity and insulation, forming an opening in a connection pad portion through exposure and development processing, and then curing the resin material by a heat treatment.

A conductive underlayer is formed on the connection pad and the protective film of the obtained semiconductor wafer by a sputtering method. A resist mask formed by photolithography is used to form, on the conductive underlayer by an electroplating method, a redistribution layer made of, for example, copper and having a thickness of about 5 μm which extends on a land formation region of the external connection electrode from the connection pad.

The semiconductor wafer having the protective film formed therein is preheated at 200° C. for one minute. The semiconductor wafer is then bias-sputtered to take an oxide film of the connection pad made of aluminum, and a titanium layer and a copper layer are formed by vacuum sputtering on the protective film as conductive underlayers of the redistribution layer.

The protective film used here is formed by using a thermosetting resin and heating the thermosetting resin at a high temperature for a long time, for example, at about 350° C. for 60 minutes.

On the other hand, in a WLP process of a semiconductor chip having memory cells such as a DRAM or an SRAM, it is desired that the thermosetting resin material for forming the protective film be cured at a low temperature to avoid characteristic degradation of the memory cells at a high temperature.

When the thermosetting resin material for the protective film is cured at a low temperature of, for example, 200° C. for 60 minutes, release of a gas such as H₂O gas from the inside of the resin is insufficient as compared to curing at a high temperature of 350° C. for 60 minutes, so that water tends to remain inside the protective film.

It is possible that water remains because of the properties of gamma butyrolactone which is generally used as a solvent of the thermosetting resin material for forming the protective film, and because an OH group existing in a precursor cannot be sufficiently dehydrated to be condensed during heat curing.

If the semiconductor wafer in which the protective film cured at a low temperature of 200° C. is formed is preheated at 200° C. for one minute, water on the surface of the protective film can be removed. However, water will seep from the inside of the protective film later when the metal underlayer, titanium, is formed on the film in the vacuum chamber. If water exists on the protective film, stable crystal growth of titanium is inhibited, and crystal grain diameters and grain boundaries of titanium on the surface of the protective film change due to the amount of water existing on the protective film.

Consequently, formation of a titanium layer having a uniform thickness is difficult, and the etching rate of the titanium layer varies within the same wafer surface or varies from wafer to wafer. This causes the following problems: the thickness of the titanium layer that remains as the metal underlayer of the redistribution layer after titanium etching varies, and the adhesion between the redistribution layer and the protective film varies within the same wafer surface or varies from wafer to wafer.

Moreover, there have recently been strong demands for reduction in the thickness, size, and weight of semiconductor product packages mainly for portable information products. The WLP is a package form suited to size reduction and thickness reduction, and has been spreading for portable products.

For example, in the typical types of latest smartphones currently widespread all over the world, about 30 to 50% or more of semiconductor devices mounted are WLPs. However, conversion of high-capacity memory chips to WLPs has not progressed, and high-capacity memory chips are not converted to WLPs even in the latest smartphones.

The conversion of high-capacity memory chips to WLPs has not progressed for the following reasons:

i) Memory products are required to miniaturize memory cells for storing information to the maximum to maximize storage capacity and maintain a chip size at the same time. Thus, a wafer having a diameter of 300 mm is often used and fabricated by using advanced design rule. For example, 50 nm or less process technology has been used to form memory cells in recent years, and miniaturization is said to be close to a physical fabrication limit.

Thus, the problem of the miniaturized memory chips is that ensuring the yield of nondefective articles in the wafer fabrication process is not easy. In addition, the memory cells degrade due to thermal stress and physical stress in the fabrication process of the WLP, and the yield of nondefective articles tends to decrease.

ii) The thermosetting resin material needs to be formed on the wafer in the WLP fabrication. If a resin insulating film is formed in a wafer having a diameter of 300 mm or more, the wafer is greatly warped; for example, the wafer is warped at about 100 μm when the diameter is 300 mm. In the WLP, fabrication process is performed in a wafer shape until the final stage of fabrication, so that the warping has an adverse effect on fabrication accuracy, and it may be difficult for a manufacturing equipment to handle or process the wafer depending on the degree of a warp of the wafer. Stress associated with the warp tends to cause degraded characteristics of memory cells and reduced yield. In particular, if the warped wafer is ground, the chip becomes slanted and nonuniform. Such effects increase if the size of the wafer is larger and if the size of the chip is larger. The effects become more serious when the wafer is ground into a smaller thickness.

The chip size is usually 40 square millimeters or more in the case of the DRAM, and the chip size is often much larger in flash memories. Moreover, there have recently been strong demands for thickness reduction in memory products that are highly needed for installation in portable products, and the wafer needs to be ground to 100 μm or less, in particular, 50 μm or less by backside grinding, so that the warping is particularly a problem.

iii) During the heat curing of a resin insulating film such as a protective film, the memory cells characteristically degrade if the film is subjected to thermal stress at the heat curing temperature for a long time.

iv) In the WLP, the yield of nondefective articles influences a WLP conversion cost per nondefective chip.

In most conventional manufacture of semiconductor packages, a test is conducted in the wafer state after the end of the wafer fabrication process, nondefective chips are selected, and nondefective articles are only assembled. This can prevent the generation of any package assembly costs for defective articles.

Meanwhile, the WLP is characterized by package formation in wafer units. Costs are generated in wafer units, and the fabrication cost per wafer is constant regardless of the yield of nondefective articles. In other words, an assembly cost for one nondefective article in the WLP fabrication is “the number of nondefective chips per wafer/a WLP fabrication cost for one wafer”. Suppose that the fabrication cost for one nondefective article is 100 when the yield of nondefective articles in a product wafer is 100%. In this case, for example, the fabrication cost for one nondefective article is about 143 when the yield of nondefective articles at the time of a wafer test of the same product is 70%.

As described above, the characteristic degradation in the WLP fabrication process not only decreases the reliability and yield of products but also increases the cost for the WLP fabrication process for one nondefective article as a result, and is a significant challenge in this respect as well.

### BRIEF SUMMARY OF THE INVENTION

A manufacturing method of a semiconductor device, the method according to the present invention comprises the steps of:

preparing a semiconductor wafer comprising memory cells, and a chip region provided with a connection pad electrically connected to the memory cells, a passivation film having an opening being formed on at least part of the connection pad;

forming a thermosetting resin material layer on the wafer, heat treating and curing the thermosetting resin material layer at a first temperature of 100° C. or more and 200° C. or less, and forming a protective film;

preheating the semiconductor wafer having the protective film formed therein at a second temperature, and removing water on the surface of the protective film;

bias sputtering on the preheated semiconductor wafer, and partly removing the surface of the connection pad;

controlling the temperature of the semiconductor wafer which has been subjected to the bias sputtering to a third temperature of 0° C. or more and 200° C. or less;

sputtering a material selected from the group consisting of titanium, titanium tungsten, tantalum, and a conductive titanium compound to form a first conductive underlayer on the protective film of the semiconductor wafer controlled at the third temperature; and

forming, on at least part of the first conductive underlayer, one element selected from a redistribution layer, an external connection electrode, a land portion of the external connection electrode, and one under-bump metal.

A semiconductor device according to the present invention comprises: a semiconductor substrate provided with memory cells, a connection pad electrically connected to the memory cells, and a fuse element; a passivation film formed by providing an opening on at least part of the semiconductor substrate; a protective film which is buried in at least a fuse opening on the fuse element and which is formed by the use of a resin material that is thermally cured at 100° C. to 200° C.; and one of a redistribution layer including a conductive underlayer made of a material selected from the group consisting of titanium, titanium tungsten, tantalum, and a conductive titanium compound provided on the semiconductor substrate via the protective film, and an external connection electrode.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing an example of the configuration of a semiconductor device according to an embodiment;

FIG. 2 is a sectional view showing another example of the configuration of the semiconductor device according to the embodiment;

FIG. 3 is a sectional view showing an example of a manufacturing process of the semiconductor device according to the embodiment;

FIG. 4 is a sectional view showing an example of the manufacturing process of the semiconductor device according to the embodiment;

FIG. 5 is a sectional view showing an example of the manufacturing process of the semiconductor device according to the embodiment;

FIG. 6 is a sectional view showing an example of the manufacturing process of the semiconductor device according to the embodiment;

FIG. 7 is a sectional view showing an example of the manufacturing process of the semiconductor device according to the embodiment;

FIG. 8 is a sectional view showing an example of the manufacturing process of the semiconductor device according to the embodiment;

FIG. 9 is a sectional view showing an example of the manufacturing process of the semiconductor device according to the embodiment;

FIG. 10 is a sectional view showing an example of the manufacturing process of the semiconductor device according to the embodiment;

FIG. 11 is a sectional view showing an example of the manufacturing process of the semiconductor device according to the embodiment;

FIG. 12 is a sectional view showing an example of the manufacturing process of the semiconductor device according to the embodiment;

FIG. 13 is a sectional view showing yet another example of the configuration of the semiconductor device according to the embodiment;

FIG. 14 is a sectional view showing yet another example of the configuration of the semiconductor device according to the embodiment;

FIG. 15 is a sectional view showing yet another example of the configuration of the semiconductor device according to the embodiment;

FIG. 16 is a sectional view showing yet another example of the configuration of the semiconductor device according to the embodiment;

FIG. 17 is a block diagram of a sputter apparatus available to the embodiment;

FIG. 18 is a flowchart showing a sputtering process using the apparatus shown in FIG. 17;

FIG. 19 is a flowchart that follows the flowchart shown in FIG. 18;

FIG. 20 is an example of a flow of a manufacturing method and an inspection of the semiconductor device according to the embodiment;

FIG. 21 is another example of the flow of the manufacturing method and the inspection of the semiconductor device according to the embodiment;

FIG. 22 is another example of the flow of the manufacturing method and the inspection of the semiconductor device according to the embodiment; and

FIG. 23 is a graph showing an example of a quantitative spectral analysis result of a low-temperature curing insulating material.

### DETAILED DESCRIPTION OF THE INVENTION

A manufacturing method of a semiconductor device according to a first embodiment includes: a step of preparing a semiconductor wafer including memory cells, and a chip region provided with a connection pad electrically connected to the memory cells, a passivation film having an opening being formed on at least part of the connection pad; a step of forming a thermosetting resin material layer on the semiconductor wafer, heat treating and curing the thermosetting resin at a first temperature of 100° C. to 200° C., and forming a protective film; a step of preheating the semiconductor wafer having the protective film formed therein at a second temperature, and removing water on the surface of the protective film; a step of bias sputtering on the preheated semiconductor wafer, and partly removing the surface of the connection pad; a step of sputtering a material selected from the group consisting of titanium, titanium tungsten, tantalum, and a conductive titanium compound to form a first conductive underlayer on the protective film of the semiconductor wafer; and a step of sputtering a material selected from the group consisting of metals such as copper and conductive compounds to form a second conductive underlayer on the first conductive underlayer.

The manufacturing method also includes controlling the temperature of the semiconductor wafer which has been subjected to the bias sputtering to a third temperature of 0° C. or more and 200° C. or less, preferably 120° C. or less; whereby a temperature of the protective film of the semiconductor wafer is controlled at the third temperature when forming a first conductive underlayer. The manufacturing method also includes a step of forming one of a redistribution layer, an external connection electrode, a land portion of an external connection electrode, and an under-bump metal of the external connection electrode on at least part of the first conductive underlayer.

A step of cutting the semiconductor wafer into pieces can be further provided. The external connection electrode is, for example, a columnar electrode, a bump, or a solder ball. As long as the electrode serves for external connection, the shape of the electrode is not limited.

A manufacturing method of a semiconductor device according to a second embodiment is similar to the method according to the first embodiment except that the semiconductor wafer further comprises a metal wiring fuse trimmed by laser and that a surface protective film is formed on the passivation film, and a protective film is further buried in a surface protective film opening on the metal wiring fuse.

A manufacturing method of a semiconductor device according to a third embodiment is similar to the method according to the first embodiment except that the semiconductor wafer further comprises an electrically trimmable fuse circuit and that the fuse circuit is electrically trimmed in a step after the step of forming the first conductive underlayer.

A semiconductor device according to a fourth embodiment includes a semiconductor substrate provided with memory cells and a fuse element, a protective film which is buried in at least a fuse opening on the fuse element and which is formed by the use of a material that is thermally cured at 100° C. to 200° C., and a redistribution layer or an external connection electrode including a first conductive underlayer made of a material selected from the group consisting of titanium, titanium tungsten, tantalum, and a conductive titanium compound provided on the semiconductor wafer via the protective film.

A semiconductor device according to a fifth embodiment includes a semiconductor substrate provided with memory cells and an electrically trimmable fuse circuit, a protective film which is formed on the semiconductor wafer and which is formed by the use of a material that is thermally cured at 100° C. to 200° C., and a redistribution layer or an external connection electrode including a first conductive underlayer made of a material selected from the group consisting of titanium, titanium tungsten, tantalum, and a conductive titanium compound provided on the semiconductor wafer via the protective film.

According to the embodiments described above, the temperature during the formation of the first conductive underlayer made of, for example, titanium can be properly controlled, so that even if the protective film is thermally cured at a temperature lower than heretofore, the first conductive underlayer made of, for example, titanium with a uniform thickness can be stably formed on the protective film. Thus, it is possible to ensure the quality of the first conductive underlayer, the second conductive underlayer made of, for example, copper, and the redistribution layer including the above underlayers, or the external connection electrode including the above underlayers. As a result, in the manufacturing method of the semiconductor device provided with the memory cells, the step that includes exposure to a high temperature for a long time can be eliminated, characteristics of the memory cells such as hold characteristics and refresh characteristics do not easily degradate, and a higher yield can be obtained than when the exposure to a high temperature for a long time is included.

Hereinafter, the embodiments will be described with reference to the drawings.

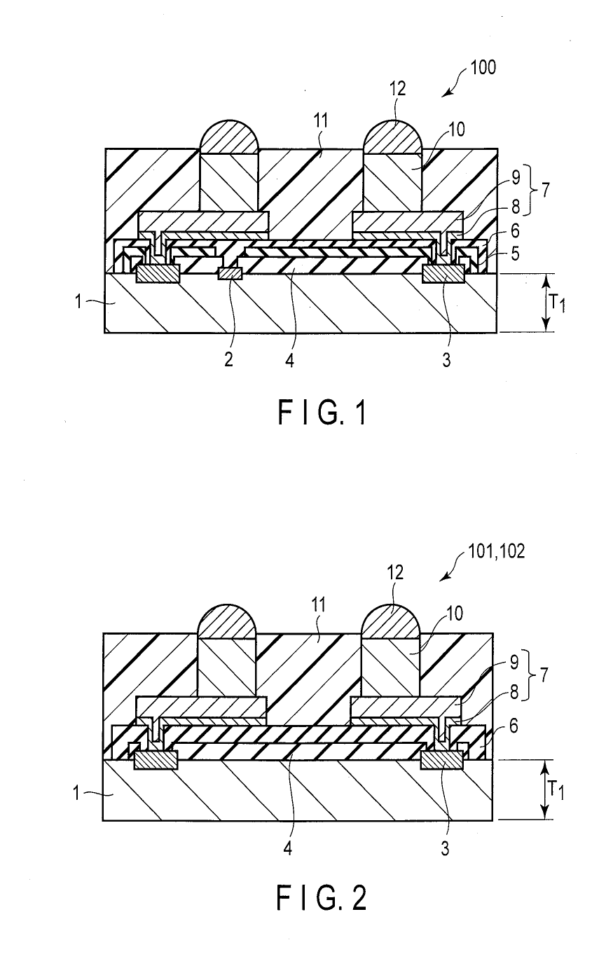

A sectional view of an example of the semiconductor device according to the second embodiment is shown in FIG. 1.

This semiconductor device is a DRAM packaged by a method called wafer level packaging (WLP), and comprises a semiconductor substrate 1. An integrated circuit (not shown) including DRAM memory cells, and a fuse 2 comprising a metal wiring line made of aluminum are provided on the upper surface of the semiconductor substrate 1.

The function of the fuse is described here.

Some semiconductor products can even change, if any, a defective part of a circuit produced in the manufacturing process to a normally operable nondefective article by replacing the defective part with a redundant circuit that has the same pattern as that of the defective part.

In the case of a semiconductor memory, a significant number of memory cells are integrated in one chip. In, for example, a DRAM in particular, if any one of the memory cells is defective, this memory chip becomes a defective article, so that the economical efficiency of the manufacture of the semiconductor memory is considerably impaired.

Thus, it is common among semiconductor memories such as the DRAM that comprise a large number of fuse circuits and redundant memory cell arrays. The fuse circuits include fuses comprising metal wiring lines of, for example, aluminum.

When a defective memory cell is replaced with a redundant memory cell, control is performed on the basis of the electrically cutoff state of the fuse circuit. The fuse circuit is generally disposed in the region of the memory chip where the memory cell array is not disposed.

The state of the fuse circuit, that is, a short-circuited state or an open state can be set, for example, by the use of laser in the manufacturing process of the semiconductor memory.

More specifically, laser is used to selectively fuse the metal wiring fuse to replace a memory cell which has been judged to be defective in a wafer test process in the manufacturing process of the semiconductor memory with a redundant memory cell. This is called fuse trimming.

It is also possible to use a circuit that can be electrically trimmed by using, as a fuse, an electric fuse circuit, that is, electrically processible element such as an antifuse or an electrically programmable nonvolatile semiconductor element for information storage instead of the metal wiring fuse.

The antifuse is an element which is electrically nonconductive in an initial state, and changes to a conductive state by dielectric breakdown resulting from high voltage application.

If the memory chip is packaged by, for example, a sealing resin, the fuse trimming is not possible in the case of the metal wiring fuse. On the other hand, if the electric fuse is used, the fuse trimming is possible even after the memory chip is packaged.

The trimming by laser needs to be performed before the formation of a protective film 6. Therefore, if troubles occur, after the formation of the protective film, due to characteristic degradation of the memory cells caused by thermal stress generated as a result of WLP fabrication or by stress associated with warping, there is no remedy for such troubles in the subsequent process.

If the electric fuse circuit is electrically trimmed before the WLP fabrication, a storage element, for example, included in the electric circuit degrades due to thermal stress or stress associated with warping, and the yield may decrease due to, for example, troubles in the electric circuit.

As described above, the fuse 2 in the semiconductor device in FIG. 1 shows a fuse comprising metal wiring lines of, for example, aluminum.

A connection pad 3 made of, for example, aluminum-based metal is provided on the upper surface of the semiconductor substrate 1 and connected to the integrated circuit.

A passivation film 4 made of, for example, silicon nitride or silicon oxide is provided on the upper surface of the semiconductor substrate 1 except for the centers of the fuse 2 and the connection pad 3 and the peripheral part of the semiconductor substrate 1. The centers of the fuse 2 and the connection pad 3 are exposed via an opening 13 provided in the passivation film 4.

A surface protective film 5 made of, for example, polyimide resin, polybenzoxazole, or phenol resin is provided on the upper surface of the passivation film 4. An opening 14 is also provided in the part of the surface protective film 5 corresponding to the opening 13 of the passivation film 4, and the opening 14 and the opening 13 are formed into one. Fuse trimming by laser is performed via the openings 13 and 14 on the fuse 2 at the stage before the formation of the protective film 6 described later.

The surface protective film 5 is covered with the protective film 6 made of a low-temperature curing insulating film material selected from the group consisting of polyimide resin, PBO, and phenol resin. The openings 13 and 14 on the fuse 2 are filled with the protective film 6. An opening 15 is provided in the protective film 6 at the position corresponding to the center of the opening 13, and the opening 15 and the opening 14 are formed into one.

Examples of photosensitive resin materials that can be used as the low-temperature curing insulating film material for the protective film are shown below in Table 1.

TABLE 1

| | | | Development type/ | | Curing | Residual |
|---|---|---|---|---|---|---|
| Product name | Company name | Resin | developer | Main solvent | temperature (° C.) | stress (Mpa) |
| LT-6300 | Toray | Polyimide | Positive/alkali | GBL/ | 170 to 200 | 15 (cured at 170° C.) |
| | | | | ethyl lactate | | 13 (cured at 200° C.) |
| LT-6500 | Toray | Polyimide | Positive/alkali | GBL/ | 170 to 200 | 21 (cured at 170° C.) |
| | | | | ethyl lactate | | 35 (cured at 200° C.) |
| WPR-5100-5051 | JSR | Phenol resin + | Positive/alkali | Ethyl lactate | 170 to 200 | 20 (cured at 200° C.) |
| | | nano rubber | | | | |
| WPR-S358P | JSR | Phenol resin | Positive/alkali | MPA/DAA | 170 to 200 | 17 (cured at 200° C.) |
| BL-300 | Asahi Kasei | PBO or polyimide | Negative/solvent base | — | 170 to 200 | 25 |
| BM-300 | Asahi Kasei | PBO or polyimide | Negative/solvent base | — | 170 to 200 | — |
| PN series | Toray | Polyimide | Negative/alkali | — | 170 to 200 | 36 |
| AH1188 | Hitachi | Phenol resin | Positive/alkali | Ethyl lactate | 170 to 200 | 20 (cured at 170° C.) |
| | Chemical | | | | | |

As shown in Table 1, residual stress provided during the curing of the insulating film material used for curing at a low temperature is lower than residual stress (about 38 Mpa) provided during the curing of a conventional insulating film material used at a curing temperature of 300° C. or more. Material having a residual stress of 25 Mpa or less currently became available.

The reason why the resin having a residual stress of 25 Mpa or less, preferably 20 Mpa or less is selected is described here.

In the DRAM, a wafer having a diameter of 300 mm or more is used, and fine exposure process technology of 50 nm or less is used in many cases for higher storage capacity. However, the warping of the wafer becomes a bigger challenge in the formation process of the WLP due to the increasing size of the wafer (wafers having a diameter of 300 mm or more in particular) and the decreasing thickness.

According to evaluations by the inventor, the following results were obtained regarding the warping amount of the wafer of 300 mm (original thickness) after the formation and curing of one resin insulating film (protective film).

Heat-curing insulating film materials
PW-1500 (heat curing temperature of 250° C., residual stress of 38 Mpa): about 100 μm
CRC-8300 (heat curing temperature of 350° C., residual stress of 38 Mpa): about 100 μm

Low-temperature curing insulating film materials
WPR-5100-5051 (heat curing temperature of 200° C., residual stress of 20 Mpa): 50 μm
LT-6300 (heat curing temperature of 200° C., residual stress of 13 Mpa): 32.5 μm.

As obvious from the above, it is possible to obtain the effect of considerably reducing warping by selecting the low-temperature curing insulating material having a low residual stress. The warping has an adverse effect on fabrication accuracy in the WLP fabrication process after the formation of the protective film, and it may be difficult for a manufacturing equipment to handle the wafer depending on the degree of the warp. In particular, the difficulty of having a great warp may be included in performing an exposure process that requires accuracy for the pattern formation of, for example, a resin film, a redistribution layer, and a UBM. If the warped wafer is ground, the chip becomes slanted and nonuniform. Such effects increase if the size of the wafer is larger and if the size of the chip is larger. The effects become more serious when the wafer is ground into a smaller thickness. In addition, stress associated with warping tends to degrade the characteristics of the memory cells and decrease the yield. No warping of the wafer is preferred.

The chip size is 40 square millimeters or more in the case of the DRAM, and the chip size is often much larger in flash memories. Moreover, there have recently been strong demands for thickness reduction in memory products that are highly needed for installation in portable products, and the wafer needs to be ground to 100 μm or less, in particular, 50 μm or less by backside grinding, so that the above-mentioned points particularly matter.

As described above, it is possible to reduce the amount of warping when the protective film is formed in the wafer having a diameter of 300 mm by using a material having a residual stress of 25 Mpa or less, preferably a material having a residual stress of 20 Mpa or less. By using such material, it was possible to manufacture a satisfactory thin memory product by grinding a large-sized chip of 40 square millimeters or more into 100 μm or less, in particular, 50 μm or less.

The content of water vapor, carbon dioxide, sulfur dioxide, and phenol in the insulating film material used for curing at a low temperature is higher than that of a conventional insulating film material used at curing temperature of 300° C. or more.

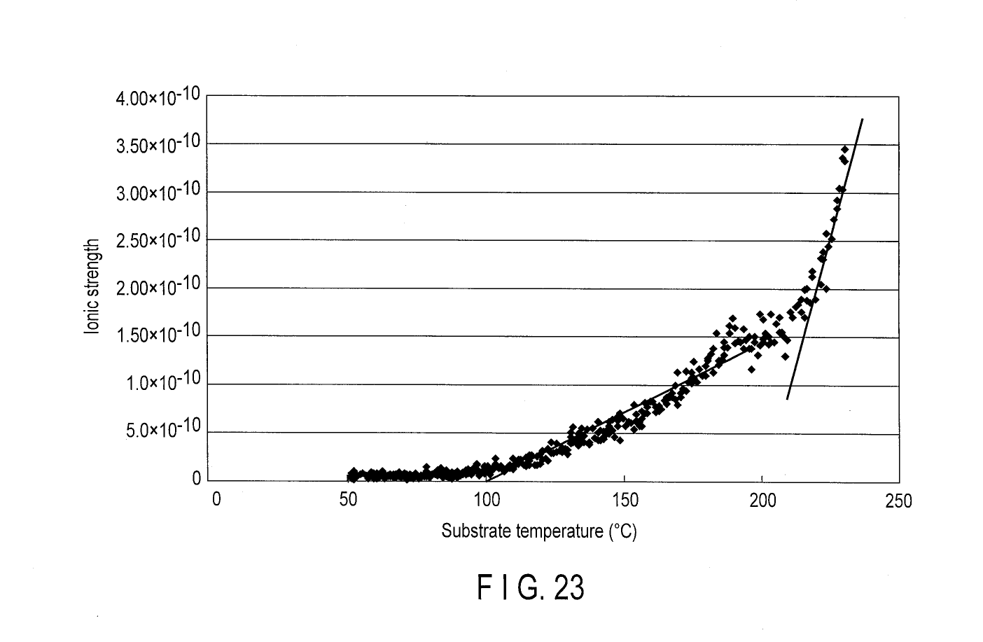

FIG. 23 shows a graph in which an example of a quantitative spectral analysis result based on thermal desorption spectrometry (TDS) of water in the insulating film material used for curing at a low temperature is plotted.

The thermal desorption spectrometry is a mass spectrometry that shows, temperature by temperature, a gas generated by vacuum heating/temperature rise. The horizontal axis indicates temperature, and the vertical axis indicates ionic strength. This graph shows a value M/z=18(H₂O).

A sample is a semiconductor wafer of 8 inches which is coated with low-temperature curing polyimide (curing temperature of 200° C.) having a thickness of about 6 to 7 μm and which has been cured at 200° C. for one hour.

As obvious from FIG. 23, water (M/z=18) is notably generated when the insulating film material reaches a level of temperature over 200° C. to about 210° C. (curing temperature plus about +10° C.). It is also obvious that generation of water (M/z=18) is extremely small at 120° C. or less.

Since the insulating film material is cured at 200° C. here, the temperature of 200° C. which is the curing temperature is the turning point. However, if the insulating film material is cured at a lower temperature, the amount of generated water is considered to significantly increase when the insulating film material is heated substantially over the level of temperature equal to the curing temperature (curing temperature plus about +10° C.)

A redistribution layer 7 is provided on the upper surface of the protective film 6. The redistribution layer 7 has a two-layer structure including a conductive underlayer 8 comprising a first conductive underlayer which is made of, for example, titanium and which is provided directly on the upper surface of the protective film 6 and a second conductive underlayer made of, for example, copper, and an upper conductive layer 9 which is made of, for example, copper and which is provided on the upper surface of the conductive underlayer 8. One end of the redistribution layer 7 is connected to the connection pad 3 via the opening 14 in the passivation film 4, the surface protective film 5, and the protective film 6.

A columnar electrode 10 made of copper is provided on the upper surface of a connection pad portion of the redistribution layer 7. A sealing film 11 made of, for example, polyimide resin, PBO, BCB, epoxy resin, or phenol resin is provided on the upper surface of the protective film 6 including the redistribution layer 7. The sealing film 11 may include a reinforcing material such as a filler. A solder terminal 12 is provided on the upper surface of the columnar electrode 10.

FIG. 2 shows a sectional view of an example of a semiconductor device manufactured by a manufacturing method according to the first embodiment, and a sectional view of an example of a semiconductor device manufactured by a manufacturing method according to the third embodiment.

As shown, a semiconductor device 101 manufactured by the manufacturing method according to the first embodiment has a configuration similar to the configuration in FIG. 1 except that the fuse 2, and the openings 13 and 14 on the fuse 2 are not provided and that the surface protective film 5 is not formed.

A semiconductor device 102 manufactured by the manufacturing method according to the third embodiment has a configuration similar to the configuration in FIG. 1 except that the fuse 2, and the openings 13 and 14 on the fuse 2 are not provided and that the unshown electrically trimmable fuse circuit is provided and that the surface protective film 5 is not formed.

### EXAMPLES

### Example 1

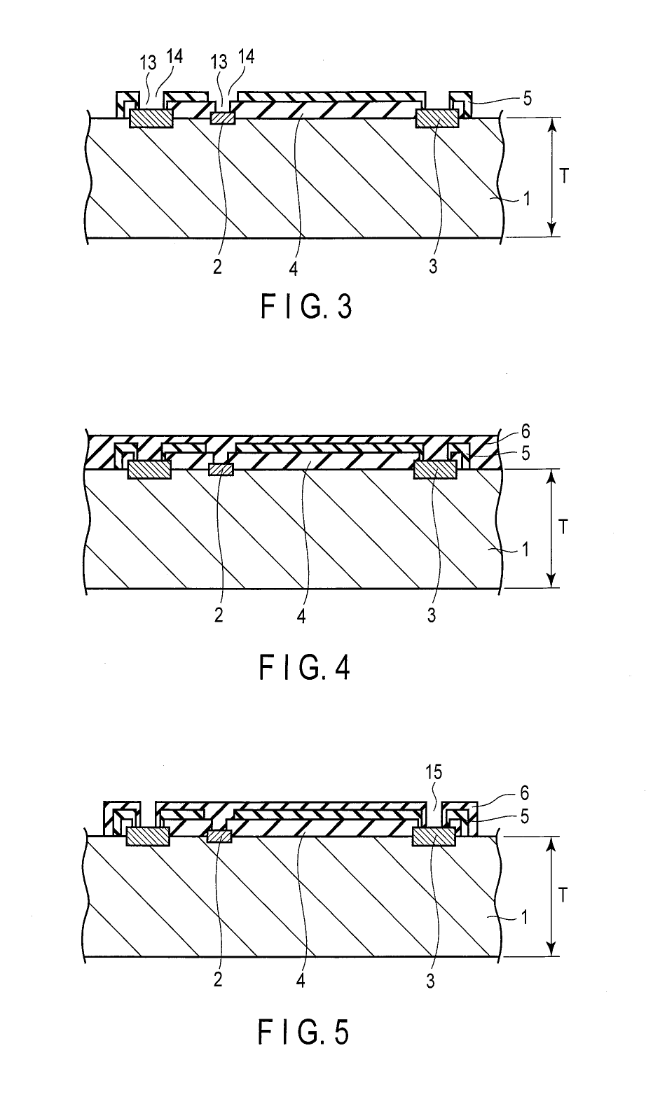

Schematic sectional views showing an example of a manufacturing method of a semiconductor device according to the embodiment is shown in FIG. 3 to FIG. 12.

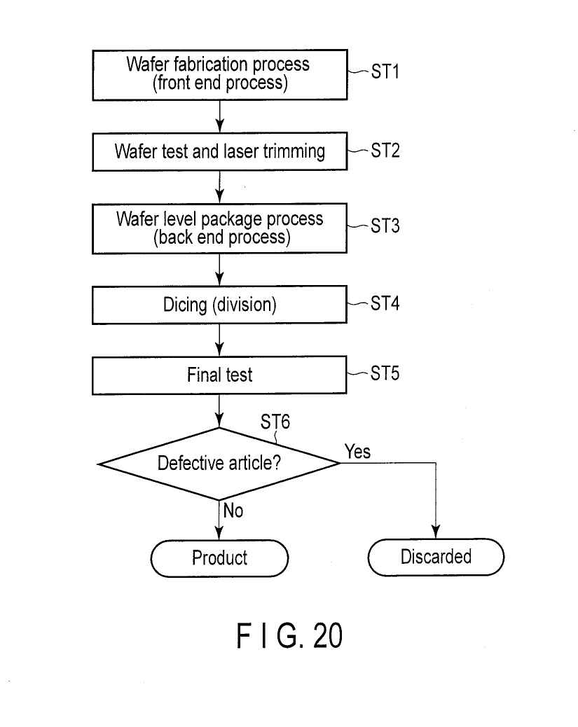

An example of a flow of a manufacturing method and an inspection of the semiconductor device according to the embodiment is shown in FIG. 20.

A semiconductor wafer 1 is prepared by a wafer fabrication process (ST1). Unshown DRAM memory cells, a fuse 2, a connection pad 3 which is made of, for example, aluminum and which is electrically connected to the DRAM memory cells, and a passivation film 4 made of, for example, silicon nitride or silicon oxide are provided on one main surface of the semiconductor wafer 1. The centers of the connection pad 3 and the fuse 2 are exposed via an opening 13 provided in the passivation film 4.

After the connection pad 3 and the passivation film 4 are covered with a surface protective film 5, an opening 14 is formed on one main surface of the semiconductor wafer 1 in the part of the surface protective film 5 corresponding to the connection pad 3 and the fuse 2 by such a method as patterning according to a photolithographic technique. As shown in FIG. 3, the semiconductor wafer 1 in which a stack composed of the passivation film 4 and the surface protective film 5 is provided is obtained.

A wafer test has already been conducted for this semiconductor wafer 1, and redundant memory cells are selected for replacing defective memory cells by fuse trimming (ST2).

One main surface of the semiconductor wafer 1 on which the stack composed of the passivation film 4 and the surface protective film 5 is provided is coated with a low-temperature curing insulating film material, and a protective film 6 curable at a low temperature is formed as shown in FIG. 4. As a result, the openings 13 and 14 on the fuse is filled with the protective film 6.

A resin having a residual stress of 25 Mpa or less and curable at a low temperature of 100° C. to 200° C. is used as the low-temperature curing insulating film material. An opening in the connection pad 3 and an opening on a dicing line need to be accurately patterned and formed by, for example, the photolithographic technique, so that a photosensitive material can be used for the protective film. Such a material is suitably selected from the group consisting of polyimide resin, polybenzoxazole (PBO), and phenol resin that are high performance in heat resistance/chemical resistance properties, electric/mechanical properties, copper electromigration resistant properties.

It is particularly preferable if a resin having a residual stress of 20 Mpa or less and curable at a low temperature of 100° C. to 200° C. can be used.

One way to apply the low-temperature curing insulating film material is to coat with a solution containing the low-temperature curing insulating film material by inkjet printing or spin coating.

Furthermore, as shown in FIG. 5, an opening 15 is formed in the part of the protective film 6 corresponding to the connection pad 3 by, for example, patterning according to the photolithographic technique.

The protective film 6 is heat treated, for example, at 200° C. for 60 minutes and cured.

The heat treatment temperature is 100° C. to 200° C. because fabrication is difficult at less than 100° C. which is the boiling point of water and because the temperature needs to be a desired temperature of about 200° C. or less to avoid characteristic degradation of the memory cells. The heat treatment temperature can be selected between 100° C. and 200° C. in consideration of the temperature that is desired for further reduction in the characteristic degradation of the memory cells, strength required for the protective film 6, reliability, and the characteristics of the low-temperature curing insulating film material to be used.

Here, when the opening 15 is formed in the protective film 6 made of a material selected from the group consisting of polyimide resin, PBO, and phenol resin, residual (not shown) which is called scum and which is made of such material may remain on the upper surface of the connection pad 3 exposed via the opening 15 in the protective film 6.

Accordingly, the residual on the protective film 6 is then removed by oxygen plasma ashing. In this case, the upper surface layer of the protective film 6 is altered under the influence of the oxygen plasma, and an unshown altered layer can be formed.

The obtained semiconductor wafer 1 is then preheated under a vacuum at 200° C. for one minute, and water on the surface of the protective film 6 is removed. The temperature of the preheating is set between 100° C. and 200° C. at which water evaporates in consideration of the temperature desired to avoid characteristic degradation of the memory cells, and in consideration of mechanical strength required for the protective film 6, reliability, and the characteristics of the low-temperature curing insulating film material to be used. If preheating is performed at a higher temperature within the above temperature range, the time required for the preheating can be reduced, and productivity (throughput) can be improved. It is particularly preferable that the upper limit temperature is set at the curing temperature of the protective film 6 or less.

A wait time of, for example, 110 seconds is provided for the preheated semiconductor wafer before the wafer temperature decreases to a desired temperature, for example, a temperature of 180° C. to 200° C. This wait time can be determined by previously measuring the time in which the temperature decreases to 180° C. to 200° C.

The preheated semiconductor wafer is subjected to bias sputtering, and a native oxide film on the connection pad 3 is removed. At the same time, the altered layer is further altered.

Here, plasma etching that uses an inert gas such as argon gas can be used for the bias sputtering.

A wait time of, for example, 12 seconds is provided for the semiconductor wafer which has been subjected to the bias sputtering before its temperature decreases to a temperature of 180° C. to 200° C., preferably 120° C. or less. This wait time can be determined by previously measuring the time in which the temperature decreases to 180° C. to 200° C.

Water is less generated on the surface of the protective film 6 at a temperature of 180° C. to 200° C., and the generation of water tends to be extremely reduced on the surface of the protective film 6 at a temperature of 120° C. or less.

Titanium is then sputtered as a first conductive underlayer.

A layer made of a material selected from the group consisting of titanium, titanium tungsten, tantalum, and a conductive titanium compound can be used as the first conductive underlayer.

The conductive titanium compound includes, for example, TiO₂, or low-order titanium oxide which is obtained by reducing TiO₂ and which is represented by a composition formula TiO_{X} (note that X is a positive real number lower than 2, preferably 1.0 to 1.8, particularly preferably 1.0 to 1.6).

The temperature (third temperature) of the conductive underlayer vacuum sputtering is set between 0° C. and 200° C. in consideration of the temperature desired to avoid characteristic degradation of the memory cells, and in consideration of the strength and reliability of the protective film 6. The upper limit temperature is preferably the first temperature, and can also be set to a temperature equal to or less than the level of temperature which is equal to the first temperature (the first temperature +10° C.), and can also be set to a temperature of more than 0° C. and equal to or less than 120° C.

Fabrication tends to be difficult at a heat treatment temperature of less than 0° C. because water solidifies at 0° C. or less. At the temperature about more than +10° C. of the curing temperature of the protective film 6, water seeps from the inside of the protective film, formation of a titanium layer (the first conductive underlayer) having a uniform thickness is difficult, and the adhesion between the redistribution layer and the protective film tends to vary.

After the sputtering of titanium, a wait time of, for example, 10 seconds is provided before the wafer temperature decreases to a temperature of 180° C. to 200° C. This wait time can be determined by previously measuring the time in which the temperature decreases to 180° C. to 200° C.

Copper is then sputtered on the titanium layer (the first conductive underlayer) as a second conductive underlayer.

As the second conductive underlayer, a metal compound can be used in addition to metals such as copper and nickel. The metal compound includes, for example, MoCu and WCu. The first conductive underlayer and the second conductive underlayer constitute a conductive underlayer 8. The process from the oxygen plasma ashing to the sputtering of the second conductive underlayer is performed under a vacuum. The vacuum in this case can be at an atmospheric pressure of 0.1 to 10⁻⁵ Pa (high vacuum). This atmospheric pressure can be lower or higher if necessary.

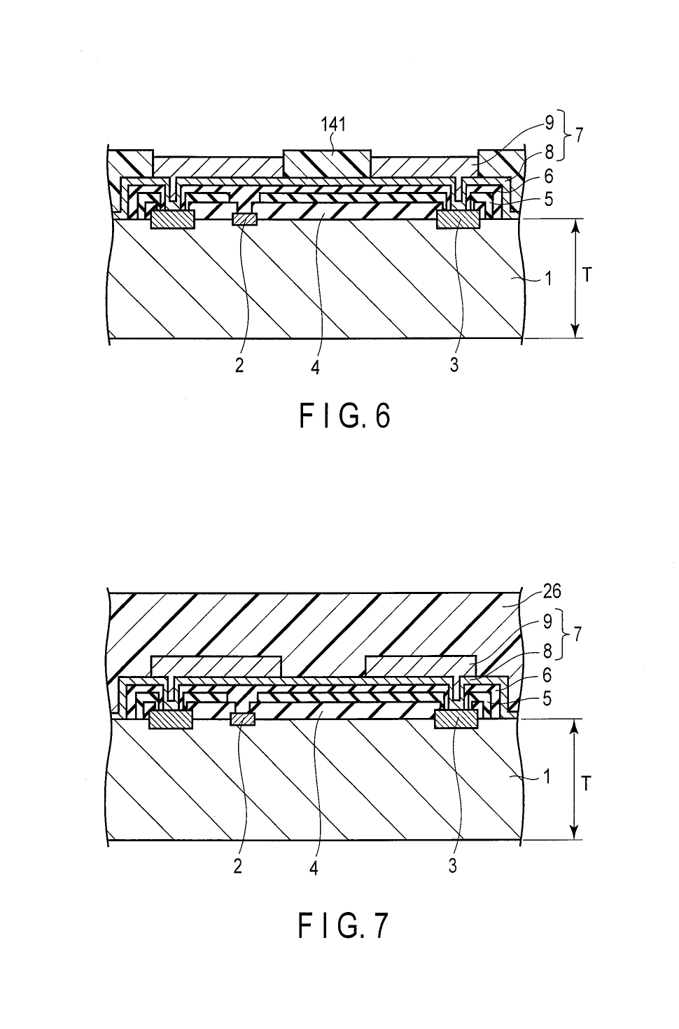

A plating resist film is then patterned and formed on the upper surface of the conductive underlayer 8. In this case, an opening is formed in the part of the plating resist film corresponding to the formation region of the upper conductive layer 9. If electrolytic plating with, for example, copper is carried out using the conductive underlayer 8 as a plating current path, the upper conductive layer 9 is then formed on the upper surface of the conductive underlayer 8 in the opening of the plating resist film as shown in FIG. 6. If the conductive underlayer 8 having a great thickness is formed, a redistribution layer comprising the conductive underlayer 8 alone can be obtained.

After the detachment of the plating resist film, a dry film resist is then laminated on the upper conductive layer 9, and an unexposed columnar electrode formation plating resist film 26 is formed, as shown in FIG. 7.

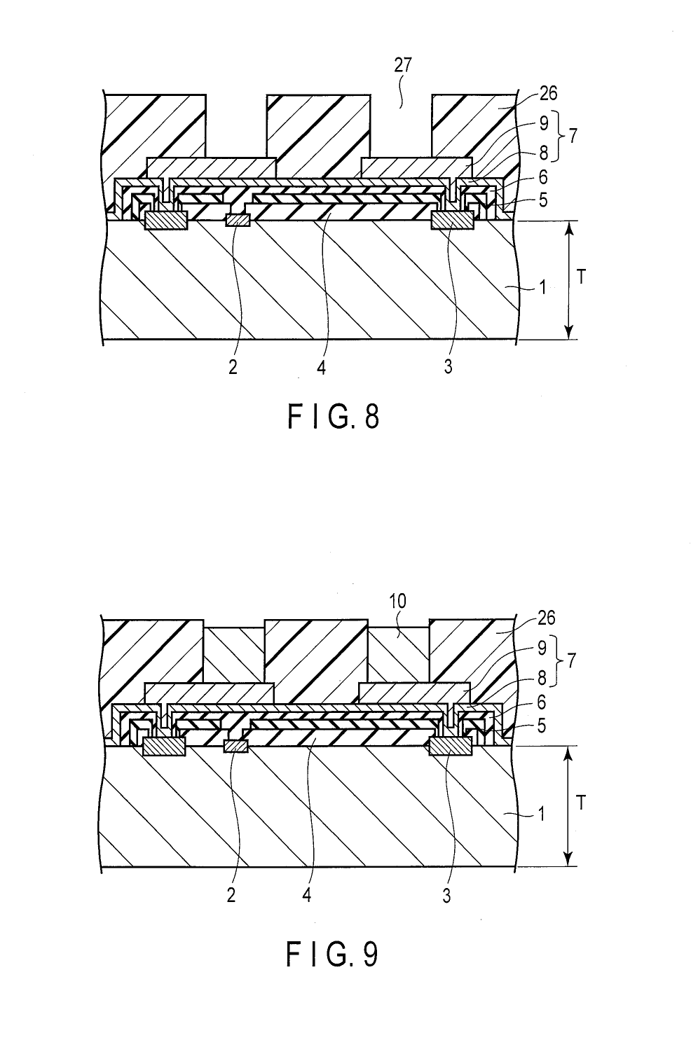

As shown in FIG. 8, exposure and development are then performed, and an opening 27 is formed in the part of a land portion of the upper conductive layer 9 corresponding to a columnar electrode formation position.

As shown in FIG. 9, if electrolytic plating with copper is carried out using the conductive underlayer 8 as a plating current path, a columnar electrode 10 is formed as an external connection electrode on the upper surface of a connection pad portion of the upper conductive layer 9 in the opening 27 of the columnar electrode formation plating resist film 26.

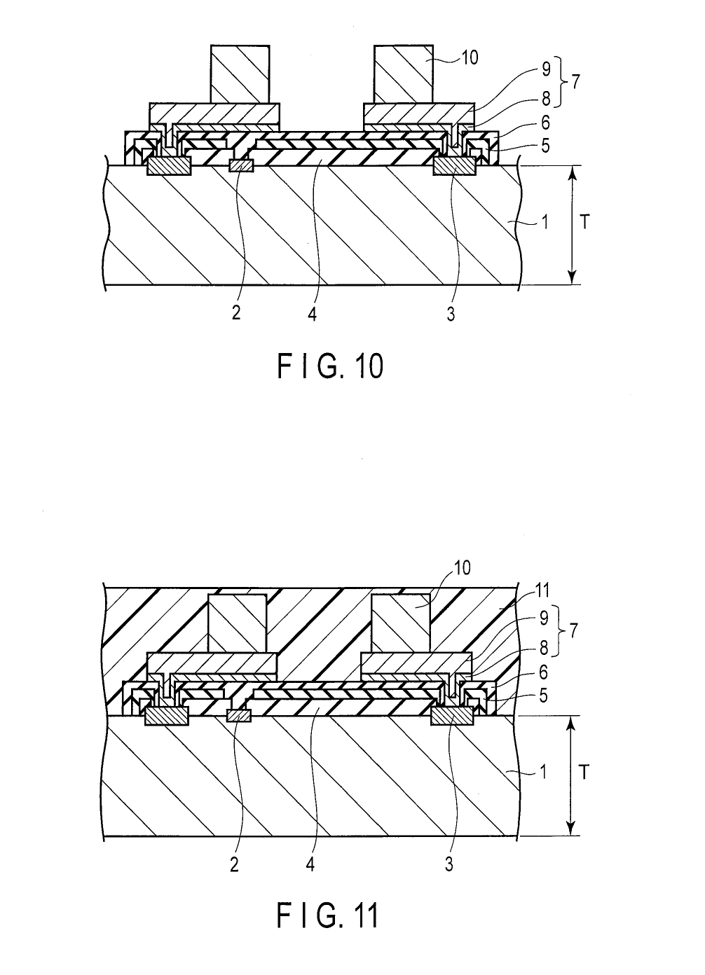

As shown in FIG. 10, the columnar electrode formation plating resist film 26 is then detached by the use of a resist detachment solution, and the upper conductive layer 9 is used as a mask to etch and remove the conductive underlayer 8 in the regions other than the region under the upper conductive layer 9. Thus, the conductive underlayer 8 only remains under the upper conductive layer 9 as shown in FIG. 10. In this state, a redistribution layer 7 having a two-layer structure is formed by the upper conductive layer 9 and the conductive underlayer 8 remaining thereunder.

If the first conductive underlayer is excessively side-etched during the etching of the conductive underlayer, the adhesion between the protective film 6 and the first conductive underlayer degrades. This is because water seeps from the inside of the protective film and formation of the first conductive underlayer having a uniform thickness is difficult at the temperature more than the level of temperature of the curing temperature of the protective film 6 (curing temperature plus about +10° C.). By properly controlling the sputtering temperature (third temperature) of the first conductive underlayer, it is possible to reduce the excessive side-etching, and maintain satisfactory adhesion between the protective film 6 and the first conductive underlayer.

As shown in FIG. 11, a sealing film 11 made of, for example, epoxy resin or polyimide resin is then formed on the upper surface of the protective film 6 including the redistribution layer 7 and the columnar electrode 10 by, for example, a screen printing method or a spin coat method so that the thickness of the sealing film 11 is slightly greater than the height of the columnar electrode 10. Therefore, in this state, the upper surface of the columnar electrode 10 is covered with the sealing film 11.

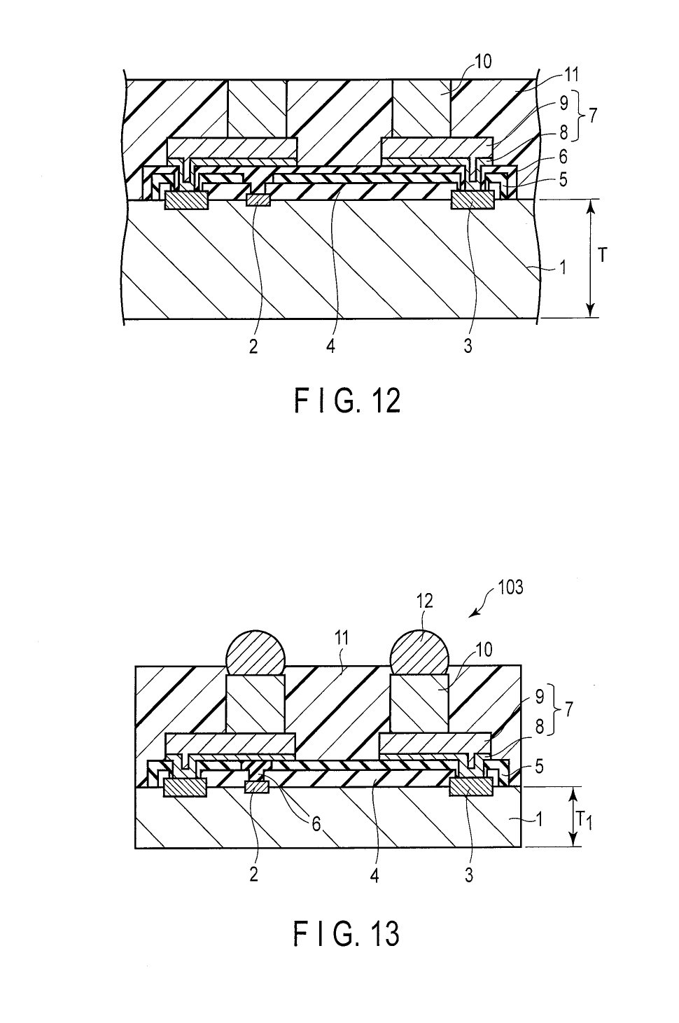

As shown in FIG. 12, the upper side of the sealing film 11 is then properly ground so that the upper surface of the columnar electrode 10 is exposed, and the upper surface of the sealing film 11 including the exposed upper surface of the columnar electrode 10 is planarized.

A solder terminal 12 is then formed on the upper surface of the columnar electrode 10, for example, by mounting a solder ball or by plating.

The rear surface of the wafer is ground at any stage of the fabrication process so that the wafer thickness will be a desired thickness of 2 μm or more to 400 μm or less. Thickness T shown in FIG. 3 to FIG. 5 indicates the thickness of the wafer substrate before the grinding of the rear surface, and is about 720 μm to 780 μm (in the case of a wafer having a bore diameter of 200 mm or a bore diameter of 300 mm). T1 indicates the thickness of the semiconductor substrate 1 after the grinding of the rear surface, and is set to 100 μm or less and further to 50 μm or less by the use of an insulating resin having a low residual stress if necessary.

In this way, a wafer level package process (ST3) is completed.

If the sealing film 11 and the semiconductor wafer 1 are then diced along unshown dicing streets (ST4), multiple semiconductor devices shown in FIG. 1 are obtained.

After this division, a final test is conducted (ST5).

Nondefective articles and defective articles are selected in accordance with the results of the final test (ST6). Semiconductor devices judged to be defective are disposed of, and semiconductor devices judged to be nondefective can be products. The final test can also be conducted in a wafer state before division by performing an operation test of the semiconductor chip in a form of the semiconductor wafer.

Although the protective film 6 is formed over the entire upper surface of the surface protective film 5 as shown in FIG. 1 in the embodiment described above, the protective film 6 can also be provided only in the opening 13 of the passivation film 4 and the opening 14 of the surface protective film 5 above the fuse 2 as shown in FIG. 13. In this case, the low-temperature curing insulating film material used for the protective film 6 may be nonphotosensitive.

The protective film 6 can be directly formed on the passivation film 4 without the formation of the surface protective film 5.

### Example 2

A DRAM wafer provided with an electrically trimmable fuse circuit (not shown) such as an antifuse element is used instead of the fuse 2. A protective film 6 is directly formed on a passivation film 4 without the formation of a surface protective film 5. In other respects, a semiconductor device shown in FIG. 2 can be obtained by forming a solder terminal 12 after forming a columnar electrode 10 and a sealing film 11 in the same manner as shown in FIG. 3 to FIG. 12. The surface protective film 5 may be formed.

When the DRAM provided with the electrically trimmable fuse (electric fuse) is converted into a WLP, the electric trimming can be performed together with the final test in the wafer state after the WLP formation or after division.

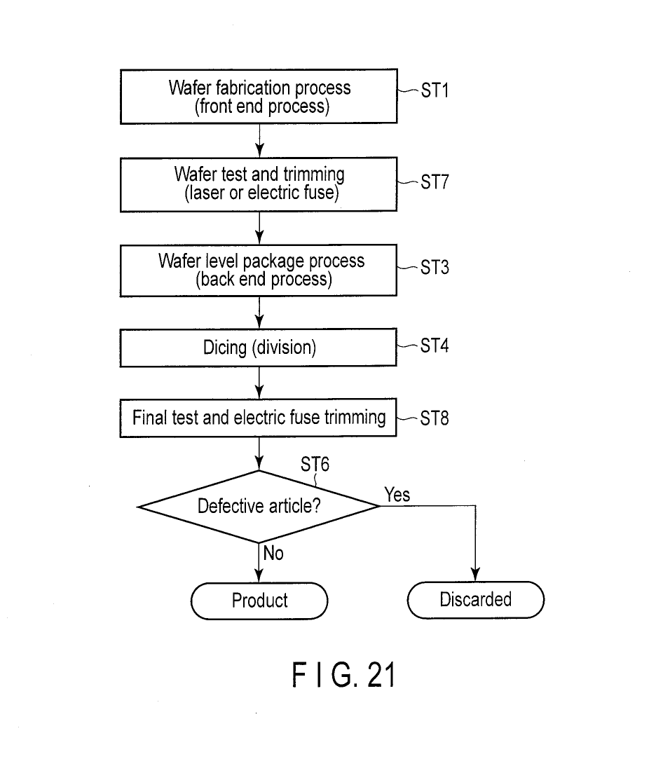

Another example of the flow of the manufacturing method and the inspection of the semiconductor device according to the embodiment is shown in FIG. 21.

This flow is similar to the flow in FIG. 20 except that the electric trimming is performed instead of laser trimming in accordance with the results of a wafer test after a wafer fabrication process (ST7) and that the electric trimming is performed in accordance with the results of a final test after dicing (ST8).

As shown in FIG. 21, trimming is performed by the use of the fuse 2 or the electric fuse during a wafer test before WLP fabrication, and electric trimming is then additionally performed in a process after the process of forming a first conductive underlayer. Thus, a higher yield can be obtained by the use of the electric fuse. It is also possible that the electric trimming also be performed only before the WLP fabrication.

However, when the electric trimming is performed before the WLP fabrication, a storage element, for example, in the electrically trimmable circuit degrades due to thermal stress or stress associated with warping, and the yield may decrease.

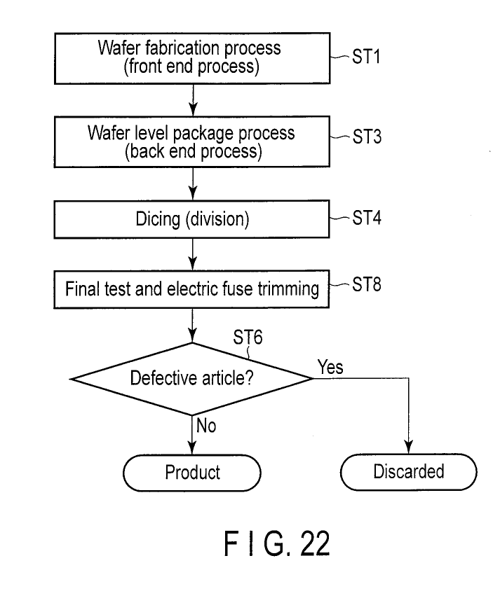

FIG. 22 shows another example of the flow of the manufacturing method and the inspection of the semiconductor device according to the embodiment.

The flow shown in FIG. 22 is similar to the flow in FIG. 21 except that the wafer test and the trimming (ST7) after the wafer fabrication process are omitted.

As shown in FIG. 22, the electric trimming can also be performed, by omitting the selection of nondefective articles based on the wafer test after the formation of the passivation film, subject to an electric characteristic inspection for selecting nondefective memory cells on the wafer performed after the process of forming the first conductive underlayer.

### Example 3

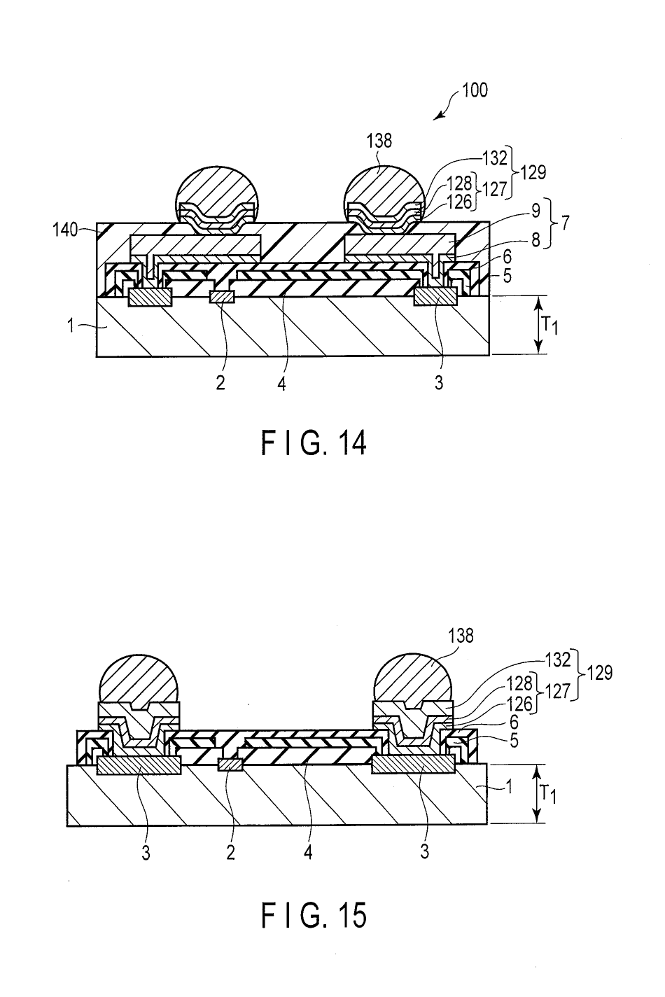

As shown in FIG. 14, a WLP can also be formed by providing a solder terminal 138 via an under-bump metal (UBM) 129 instead of the columnar electrode 10.

In the semiconductor device shown in FIG. 14, an upper conductive layer formation plating resist film on the semiconductor substrate 1 having the same configuration as that in FIG. 6 is detached by the use of a resist detachment solution after the formation of the upper conductive layer 9 on the upper surface of the protective film 6, and the upper conductive layer 9 is used as a mask to etch and remove the conductive underlayer 8 in the regions other than the region under the upper conductive layer 9. Thus, the conductive underlayer 8 only remains under the upper conductive layer 9. In this state, a redistribution layer 7 having a two-layer structure is formed by the upper conductive layer 9 and the conductive underlayer 8 remaining thereunder.

Furthermore, the main surface of the semiconductor wafer 1 is coated with a solution containing the low-temperature curing insulating film material to cover the redistribution layer 7 and the protective film 6, and a redistribution layer protective film 140 is formed.

A photosensitive material having a residual stress of 25 Mpa or less and curable at a low temperature of 100° C. to 200° C. which is selected from the group consisting of polyimide resin, polybenzoxazole (PBO), and phenol resin is used as the low-temperature curing insulating film material for the redistribution layer protective film 140, as in the case of the protective film 6. It is also particularly preferable if a resin having a residual stress of 20 Mpa or less and curable at a low temperature of 100° C. to 200° C. can be used.

An opening is then formed in the part of the redistribution layer protective film 140 corresponding to an external connection electrode land by, for example, patterning according to the photolithographic technique. The redistribution layer protective film 140 is similar to the protective film 6 in other respects such as how to apply the low-temperature curing insulating film material and how to form and cure the redistribution layer protective film.

On the redistribution layer protective film 140 including the opening, a first conductive underlayer 126 and a second conductive underlayer 128 are then sequentially formed, and a conductive underlayer 127 comprising the first conductive underlayer 126 and the second conductive underlayer 128 is formed. The material, formation method, and conditions of the conductive underlayer are similar to those for the formation of the conductive underlayer 8 on the protective film 6 including the fact that the process from the oxygen plasma ashing to the sputtering of the second conductive underlayer 128 is performed under a vacuum. Consequently, it is possible to satisfactorily form the first conductive underlayer 126 of the UBM layer having a uniform quality without the variation of the adhesion between the first conductive underlayer 126 and the redistribution layer protective film.

A plating resist film is then patterned and formed on the upper surface of the conductive underlayer 127. In this case, an opening is formed in the part of the plating resist film corresponding to the formation region of the UBM. If electrolytic plating with, for example, copper is carried out using the conductive underlayer 8 as a plating current path, an upper conductive layer 132 having a thick copper layer is formed on the upper surface of the conductive underlayer 127 in the opening of the plating resist film as shown in FIG. 6. If the conductive underlayer 127 having a great thickness is formed, a UBM comprising the conductive underlayer alone can be obtained. The under-bump metal layer (UBM layer) 129 refers to a combination of the conductive underlayer 127 and the upper conductive layer 132 under the bump.

A solder terminal 138 is then formed on the UBM 129, for example, by mounting a solder ball or by plating.

The rear surface of the wafer is ground in a similar manner at any stage of the fabrication process so that the wafer thickness will be a desired thickness of 2 μm or more to 400 μm or less. The thickness can also be 100 μm or less and 50 μm or less by the use of an insulating resin having a low residual stress if necessary.

External connection electrodes having various shapes such as a copper pillar can be provided on the land.

Although the redistribution layer protective film equivalent to the protective thermosetting resin material is used in the present example, the material is not limited, and any other resin materials may be used as long as the characteristics of the semiconductor device permit.

As in Example 2, it is possible to apply a DRAM wafer provided with an electrically trimmable fuse circuit, instead of the semiconductor wafer provided with the fuse 2. It is also possible to apply the manufacturing method and the inspection flow shown in FIG. 21 and FIG. 22.

For example, when the trimming is performed by the use of the electric fuse after the formation of the protective film, the low-temperature curing insulating film material is not used for the formation of the protective film 6, and the low-temperature curing insulating film material can be used for the redistribution layer protective film. In this case, it is possible to satisfactorily form the conductive underlayer of the UBM layer by using a manufacturing method similar to that in the present example.

### Example 4

As shown in FIG. 15, the solder terminal 138 and external connection electrodes having various shapes such as a copper pillar can be provided above the connection pad 3 via the opening of the protective film 6 without the formation of the redistribution layer.

In the semiconductor device shown in FIG. 15, the first conductive underlayer 126 is formed in close contact with the protective film 6 on the side surface of the opening on the connection pad 3 and on the upper surface of the protective film 6. The material, formation method, and conditions of the conductive underlayer are similar to those for the formation of the conductive underlayer 8 of the redistribution layer 7 on the protective film 6 including the fact that the process from the oxygen plasma ashing to the sputtering of the second conductive underlayer 128 is performed under a vacuum. Consequently, it is possible to satisfactorily form the first conductive underlayer 126 of the UBM layer having a uniform quality without the variation of the adhesion between the first conductive underlayer 126 and the protective film 6. A solder terminal 138 is formed on the conductive layer (UBM layer) 129 comprising the upper conductive layer 132 formed by electrolytic plating with, for example, copper above the conductive underlayer 127 comprising the first conductive underlayer 126 and the second conductive underlayer 128.

The first conductive underlayer 126, the second conductive underlayer 128, and the upper conductive layer 132 are sequentially formed on the opening 14 and the protective film 6 of the semiconductor substrate 1 having the same configuration as that in FIG. 5, and the upper conductive layer 132 is used as a mask to etch and remove the second conductive underlayer 128 and the first conductive underlayer 126. As a result, the UBM layer 129 comprising the conductive underlayer 127 and the upper conductive layer 132 is formed. The solder terminal can be formed, for example, by using a solder ball or by plating.

The rear surface of the wafer is ground in a similar manner at any stage of the fabrication process so that the wafer thickness will be a desired thickness of 2 μm or more to 400 μm or less. The thickness can also be 100 μm or less and 50 μm or less by the use of an insulating resin having a low residual stress if necessary. Example 4 is similar to Examples 1 to 3 in that multiple semiconductor devices are obtained by dicing, in that the final test is conducted, and in other respects.

It is possible to apply a DRAM wafer provided with an electrically trimmable fuse circuit, instead of the semiconductor wafer provided with the fuse 2.

### Example 5

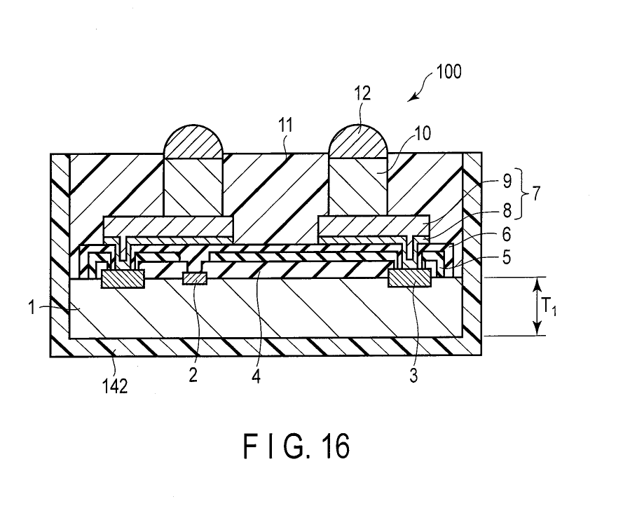

As shown in FIG. 16, the low-temperature curing insulating film material can be used to further form a protective film 142 comprising a side protective film and/or a rear protective film in the semiconductor device shown in FIG. 1. A side protective film and/or a rear protective film can be further formed in the semiconductor devices shown in FIG. 12, FIG. 13, FIG. 14, and FIG. 15, respectively.

The side protective film and the rear protective film are located relative to a memory cell formation region across, for example, silicon. However, to avoid characteristic degradation of the memory cells, it is preferable to form the protection films by using resin materials such as epoxy resin, BCB, polyimide resin, polybenzoxazole (PBO), and phenol resin that are cured at 100° C. to 200° C. Materials having a residual stress of 25 Mpa or less can be selected for the side protective film and the rear protective film. It is particularly preferable if a material having a residual stress of 20 Mpa or less can be used.

In the cases described above in Example 1 and Example 2, the DRAM having the function to change defective memory cells to redundant memory cells by the laser fuse or the electrically trimmable fuse circuit (electric fuse) is converted to the WLP. However, the present invention is not limited to this, and is widely advantageous to the WLP conversion of semiconductor devices comprising memory cells of other random access memories (RAM) such as an SRAM, and semiconductor devices comprising other memory cells such as a flash memory or a read only memory (ROM).

Furthermore, the present invention is applicable to various semiconductor devices including electronic elements and circuits (e.g. magnetoresistive elements, magnetic impedance elements, and piezoelectric resistive semiconductor pressure sensors) that may be affected and cause problems such as characteristic degradation when a heat treatment is conducted in the wafer level package process.

In Examples 3 and 4, the protective film 6 can also be provided only in the opening 13 of the passivation film 4 and the opening 14 of the surface protective film 5 above the fuse 2, as in FIG. 13. In this case, the low-temperature curing insulating film material used for the protective film 6 may be nonphotosensitive.

The surface protective film 5 does not always need this configuration, and the surface protective film 5 may be omitted. In this case, the protective film 6 is formed on the passivation film 4.

Although the columnar electrode is used as the external connection electrode in Examples 1, 2 and 5, the present invention is not limited to this. Electrodes having various shapes such as a solder terminal and a copper pillar can be used as the external connection electrodes.

In Examples 1 to 5, the solder terminal may be unnecessary depending on the purpose.

To avoid characteristic degradation of the memory cells, it is also preferable to form the surface protective film 5 by using a resin material that is cured at 100° C. to 200° C. Moreover, it is preferable to select a resin material having a residual stress of 25 Mpa or less, in particular, a resin material having a residual stress of 20 Mpa or less.

The sealing film 11, the side protective film, and the rear protective film are located relative to the memory cell formation region across, for example, the protective film and silicon. However, to avoid characteristic degradation of the memory cells, it is preferable to form the films by using resin materials that are cured at 100° C. to 200° C. It is particularly preferable if materials each having a residual stress of 25 Mpa or less or a residual stress of 20 Mpa or less can be selected for the sealing film 11, the side protective film, and the rear protective film. In this case, the residual stress of the protective film 6 can be lower than the residual stress of the sealing film 11, the redistribution layer protective film, the side protective film, or the rear protective film.

In Examples 1 to 5, it is not always necessary to use a low-temperature curing resin for the surface protective film 5, the sealing film 11, the redistribution layer protective film, the side protective film, or the rear protective film. It is also possible to use resin materials other than the low-temperature curing resin materials in consideration of economical efficiency and other characteristics when there is no trouble in view of the characteristics of internal circuits. In this case, the residual stress of the protective film 6 may be lower than the residual stress of one of the surface protective film 5, the sealing film 11, the redistribution layer protective film, the side protective film, and the rear protective film.

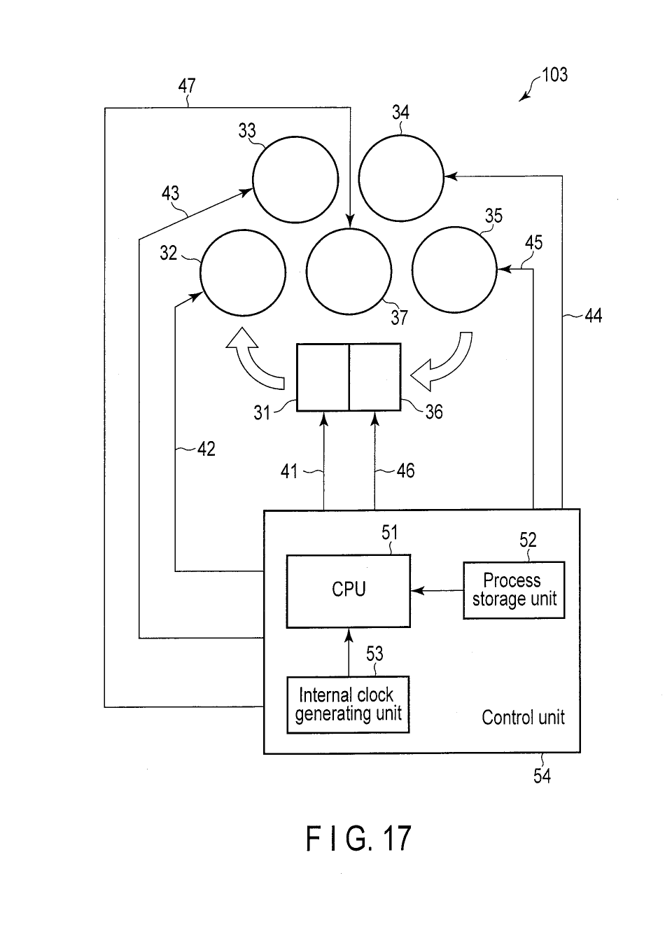

A block diagram of a sputter apparatus available to Examples is shown in FIG. 17.

The sputter apparatus shown in FIG. 17 can be used to form the first and second conductive underlayers after the stack of the passivation film, the surface protective film, and the protective film, and the opening provided in the part corresponding to the connection pad are formed on the semiconductor wafer which is provided with the DRAM memory cells, the fuse, and the connection pad connected to the DRAM memory cells and made of aluminum.

As shown, a sputter apparatus 103 is kept in a vacuum. The sputter apparatus 103 has a wafer unload unit 31 which loads the semiconductor wafer into a predetermined chamber in the apparatus 103, a preheat chamber 32 to preheat the semiconductor wafer, an RF chamber 33 to bias-sputter the connection pad of the preheated semiconductor wafer, a Ti sputter chamber 34 to sputter the titanium layer as the first conductive underlayer after the bias sputtering, a Cu sputter chamber 35 to sputter a copper layer on the titanium layer as the second conductive underlayer, a wafer unload unit 36 which unloads the semiconductor wafer on which the copper layer has been sputtered, and a carrying robot 37 which carries the semiconductor wafer to each of the units 31, 32, 33, 34, 35, and 36. Each of the units 31, 32, 33, 34, 35, and 36 and the wafer carrying robot 37 are connected to a control unit 54. The control unit 54 has a CPU 51, and a process storage unit 52 and an internal clock generating unit 53 that are connected to the CPU 51.

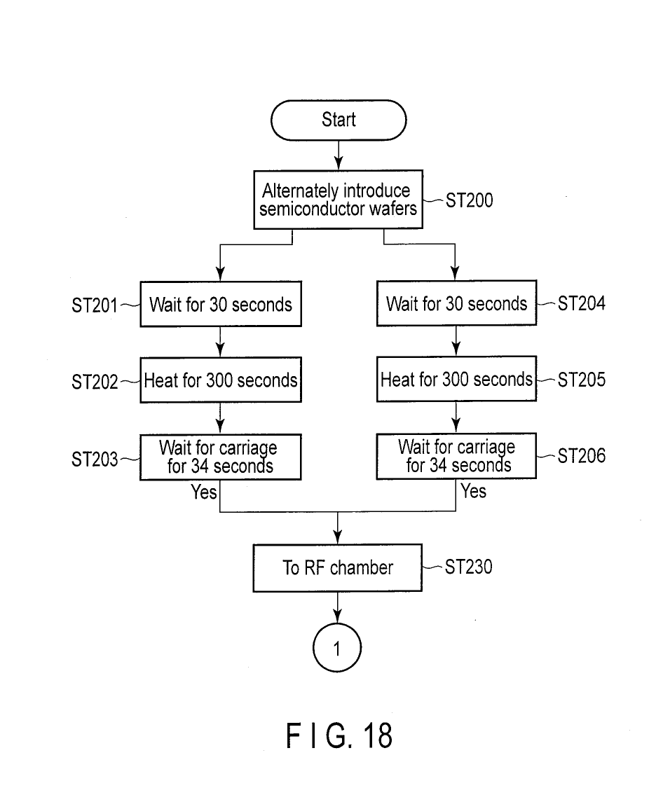

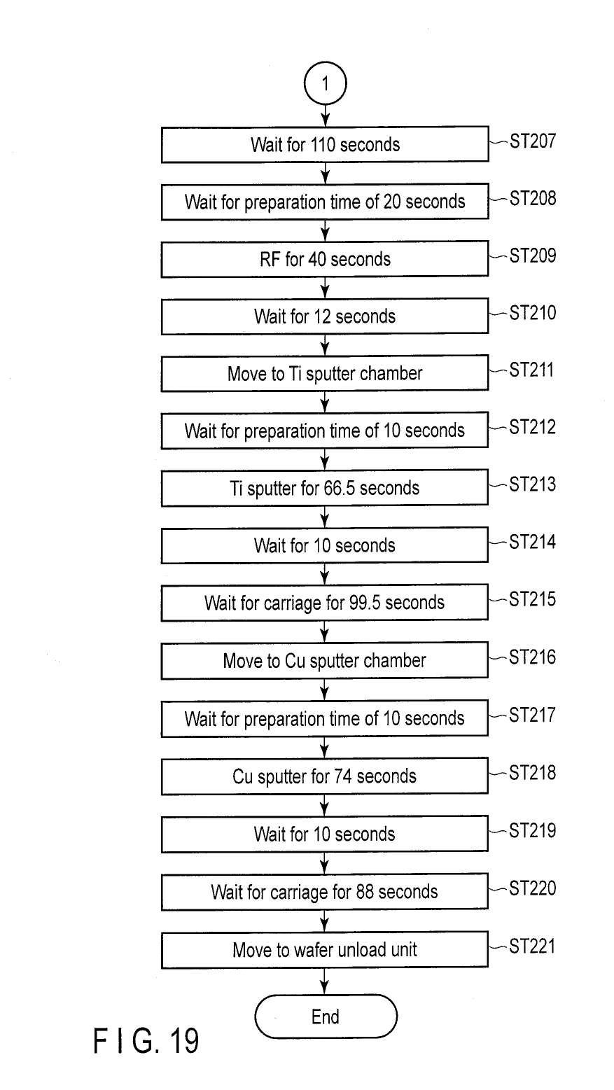

FIG. 18 and FIG. 19 show flowcharts showing examples of the processes of preheating, bias sputtering, sputtering of the titanium layer, and sputtering of the copper layer when the sputter apparatus shown in FIG. 17 is used.

According to the method shown in FIG. 18, the preheat chamber 32 has a preheat chamber A and a preheat chamber B. The wafer unload unit 31 can alternately load the semiconductor wafer into the preheat chamber A and the preheat chamber B in response to a wafer load unit control signal 41 from the control unit 54 (ST200).

As shown, the first semiconductor wafer is first mounted on the preheat chamber A, and there is a wait of 30 seconds in response to a preheat chamber control signal 42 from the control unit 54 (ST201). The semiconductor wafer is heated at 180° C. to 200° C. for 300 seconds (ST202), and there is a wait of 34 seconds (ST203). Similar processing is also performed in the preheat chamber B (ST204, ST205, and ST206). Therefore, the semiconductor wafers are alternately moved to the RF chamber from the preheat chamber A and the preheat chamber B every 182 seconds by the wafer carrying robot 37 in response to a wafer carrying robot control signal 47 from the control unit 54 (ST230).

Thus, two semiconductor wafers are alternately introduced into the preheat chamber A and the preheat chamber B, so that the preheat process having a total wait time of 30 seconds, a heating time of 300 seconds, and a carriage wait time of 34 seconds can be apparently reduced by half to 182 seconds.

The semiconductor wafer moved to the RF chamber first waits for 110 seconds in response to an RF chamber control signal 43 from the control unit 54 (ST207). The semiconductor wafer is cooled to 200° C. or less, preferably to 120° C. or less. After a preparation time of 20 seconds has passed (ST208), the semiconductor wafer is subjected to sputtering for 40 seconds (ST209). After an oxide film on the surface of the aluminum connection pad has been removed, there is a wait of 12 seconds (ST210), and the semiconductor wafer is cooled to 200° C. or less. The semiconductor wafer is then moved to the Ti sputter chamber in response to the wafer carrying robot control signal 47 from the control unit 54 (ST211).

The semiconductor wafer moved to the Ti sputter chamber passes a preparation time of 10 seconds in response to a Ti sputter chamber control signal 44 from the control unit 54 (ST212), and Ti is sputtered for 66.5 seconds (ST213). The semiconductor wafer waits for 10 seconds (ST214), and further waits for carriage for 95.5 seconds (ST215), and thereby cooled to 200° C. or less. The semiconductor wafer is then moved to the Cu sputter chamber by the wafer carrying robot 37 in response to the wafer carrying robot control signal 47 from the control unit 54 (ST216).

The semiconductor wafer moved to the Cu sputter chamber passes a preparation time of 10 seconds in response to a Cu sputter chamber control signal 45 from the control unit 54 (ST217), and Cu is sputtered for 74 seconds (ST218). The semiconductor wafer waits for 10 seconds (ST219), and waits for carriage for 88 seconds (ST220). The semiconductor wafer is then moved to the wafer unload unit by the wafer carrying robot 37 in response to the wafer carrying robot control signal 47 from the control unit 54, and then unloaded from the sputter apparatus.

In this way, the preheat process (ST201, ST202, ST203 and ST204, ST205, and ST206), the bias sputtering process (ST207, ST208, ST209, and ST210), the Ti sputtering process (ST212, ST213, ST214, and ST215), and the Cu sputtering process (ST217, ST218, ST219, and ST220) are each completed within 182 seconds. Therefore, the processes can be efficiently carried forward.

The processes in this sputter apparatus are conducted in the sputter apparatus under a vacuum. Therefore, if the temperature is controlled without wait times, the temperature of the water gradually increases with the advance of the processes; for example, the temperature of the water increases to 200° C. in the preheating, 230° C. in the bias sputtering, 250° C. in the Ti sputtering, and 270° C. in the Cu sputtering. As a result, water is generated on the surface of the protective film, and the crystal grain diameter and grain boundary of titanium on the surface of the protective film are changed by the amount of water on the protective film.

In contrast, according to the present invention, Ti is sputtered at 200° C. or less, preferably at 120° C. or less. Therefore, the wafer temperature in the Ti sputtering process is controlled so that the temperature will be the above-mentioned temperature. More specifically, the temperature is monitored immediately before the Ti sputtering process to wait until the temperature will be a predetermined temperature or less, or a preset wait time is provided on the basis of a temperature drop per unit time. The latter is advantageous to process management. The presence of a cooling mechanism has such an advantage that the wait time can be shorter or zero.

As described above, the temperature conditions are properly set for the formation of the protective film by the use of the insulating film material which has a low residual stress and which is curable at a low temperature, and for the following sputtering. Consequently, it is possible to eliminate the process that includes a high temperature for a long time in the WLP conversion of a semiconductor chip having memory cells such as the DRAM or SRAM, and reduce warping. Characteristic degradation of the memory cells can be reduced and the yield can be improved.

The use of the resin having a low residual stress to reduce the warping of the wafer is significantly advantageous especially when a memory chip manufactured from a wafer having a diameter of 300 mm or more is reduced in thickness by the grinding of the rear surface in the WLP fabrication.

In the case of a memory which is trimmed by the metal wiring fuse, laser trimming needs to be performed before the formation of the protective film 6. Therefore, it is possible to minimize characteristic degradation of the memory cells resulting from thermal stress or stress associated with warping caused by the WLP fabrication after the formation of the protective film, and improve the yield.

Trimming does not enable the rescue of all the memory chips. Therefore, when the trimming by the electric fuse is performed after the WLP fabrication, an improvement in the yield of nondefective articles during the trimming can be expected by the reduction of degradation resulting from thermal stress or stress associated with warping. Moreover, when a memory product equipped with the electric fuse is fabricated into a WLP and trimming is performed after the WLP fabrication, the wafer test process for the selection of nondefective articles is not always needed. Therefore, this process can be omitted, and the effect of resulting cost reduction can be expected.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device, the method comprising the steps of:
preparing a semiconductor wafer comprising memory cells, and a chip region provided with a connection pad electrically connected to the memory cells, a passivation film having an opening being formed on at least part of the connection pad;
forming a thermosetting resin material layer on the wafer, heat treating and curing the thermosetting resin material layer at a first temperature of 100° C. to 200° C. or less, and forming a protective film;
preheating the semiconductor wafer having the protective film formed therein at a second temperature, and removing water on the surface of the protective film;
bias sputtering on the preheated semiconductor wafer, and partly removing the surface of the connection pad;
controlling the temperature of the semiconductor wafer which has been subjected to the bias sputtering to a third temperature of 0° C. to 200° C.;
sputtering a material selected from the group consisting of titanium, titanium tungsten, tantalum, and a conductive titanium compound to form a first conductive underlayer on the protective film of the semiconductor wafer controlled at the third temperature; and
forming, on at least one part of the first conductive underlayer, one element selected from a redistribution layer, an external connection electrode, a land portion of the external connection electrode, and one under-bump metal.

2. The method according to claim 1, in which the semiconductor wafer comprises a metal wiring fuse trimmed by laser,
in which forming the protective film comprises filling a fuse opening with the protective film, and
which further comprises a step of cutting the semiconductor wafer into pieces after the step of forming one of the redistribution layer, the external connection electrode, the land portion of the external connection electrode, and the under-bump metal.

3. The method according to claim 1, wherein the semiconductor wafer comprises an electrically trimmable fuse circuit, and
the method further comprising electrically trimming the fuse circuit in a step after forming the first conductive underlayer.

4. The method according to claim 3, wherein the electric trimming is performed in a wafer state.

5. The method according to claim 3, further comprising dividing the semiconductor wafer into pieces to obtain semiconductor devices, the electric trimming being performed for each of the divided semiconductor devices.

6. The method according to claim 1, wherein the semiconductor wafer comprises an electrically trimmable fuse circuit, and
electric trimming is performed by the use of the fuse circuit during a wafer test, and the fuse circuit is then further electrically trimmed in a step after the step of forming the first conductive underlayer.

7. The method according to claim 1, wherein the thermosetting resin material is a photosensitive resin, and the formation of the protective film comprises a step of patterning the thermosetting resin material layer in accordance with a photolithographic technique.

8. The method according to claim 1, wherein the protective film is formed by the use of at least one photosensitive resin selected from the group consisting of polyimide resin, polybenzoxazole, and phenol resin material, and the residual stress thereof is 25 Mpa or less.

9. The method according to claim 1, wherein the third temperature is a temperature of not more than 120° C. or a temperature of not more than the first temperature.

10. The method according to claim 1, wherein the preheating comprises controlling at the second temperature, the bias sputtering comprises controlling at the third temperature, and forming the first conductive underlayer comprises controlling at the third temperature, and
the preheating, the reverse sputtering, and the forming the first conductive underlayer are successively performed under a vacuum.

11. A semiconductor device comprising: a semiconductor substrate provided with memory cells, a connection pad electrically connected to the memory cells, and a fuse element; a passivation film formed by providing an opening on at least part of the semiconductor substrate; a protective film which is buried in at least a fuse opening on the fuse element and which is formed by the use of a resin material that is thermally cured at 100° C. to 200° C.; and one of a redistribution layer including a conductive underlayer made of a material selected from the group consisting of titanium, titanium tungsten, tantalum, and a conductive titanium compound provided on the semiconductor substrate via the protective film, and an external connection electrode.

12. The semiconductor device according to claim 11, wherein the protective film is formed by the use of at least one photosensitive resin selected from the group consisting of polyimide resin, polybenzoxazole, and phenol resin material, and the residual stress thereof is not more than 25 Mpa.

13. The semiconductor device according to claim 11, wherein the thickness of the substrate is 2 μm to 100 μm.

14. The semiconductor device according to claim 11, wherein the area of the substrate is not less than 40 square millimeters.

15. The semiconductor device according to claim 11, further comprising at least one insulating layer which is provided on at least part of the upper surface, side surface, and rear surface of the semiconductor substrate, and is made of a resin material which is thermally cured at 100° C. to 200° C. is.

16. The semiconductor device according to claim 15, wherein the residual stress of the protective film is lower than the residual stress of the insulating layer.

17. The semiconductor device according to claim 15, in which the insulating layer comprises, on the protective film, a redistribution layer protective film formed over at least part of the redistribution layer,
which further comprises an external connection electrode which includes a conductive underlayer made of a material selected from the group consisting of titanium, titanium tungsten, tantalum, and is provided via an opening of the redistribution layer protective film, and
in which the redistribution layer protective film has a residual stress of not more than 25 Mpa, and is formed by the use of at least one photosensitive resin selected from the group consisting of polyimide resin, polybenzoxazole, and phenol resin material.

18. A semiconductor device comprising: a semiconductor substrate which is provided with memory cells and which comprises a connection pad electrically connected to the memory cells, and an electrically trimmable fuse circuit connected to the memory cells; a passivation film formed by providing an opening on at least part of the semiconductor substrate; a protective film which is formed on the passivation film and which is formed by the use of a resin material that is thermally cured at 100° C. to 200° C.; and one of a redistribution layer including a conductive underlayer made of a material selected from the group consisting of titanium, titanium tungsten, tantalum, and a conductive titanium compound provided on the semiconductor substrate via the protective film, and an external connection electrode.

19. The semiconductor device according to claim 18, wherein the protective film is formed by the use of at least one photosensitive resin selected from the group consisting of polyimide resin, polybenzoxazole, and phenol resin material, and the residual stress thereof is not more than 25 Mpa.

20. The semiconductor device according to claim 18, wherein the thickness of the substrate is 2 μm to 100 μm, the area of the substrate is not more than 40 square millimeters, and the residual stress of the protective film is not more than 25 Mpa.
